(19) United States
(12) Patent Application Publication
(10) Pub. No.: US 2024/0306378 A1
(43) Pub. Date: Sep. 12, 2024

(54) SEMICONDUCTOR DEVICE

(71) Applicant: SAMSUNG ELECTRONICS CO., LTD., Suwon-si (KR)

(72) Inventor: Junhyeok AHN, Suwon-si (KR)

(21) Appl. No.: 18/241,335

(22) Filed: Sep. 1, 2023

(30) Foreign Application Priority Data
Mar. 8, 2023 (KR) 10-2023-0030718

(51) Int. Cl. H10B 12/00

(52) U.S. Cl. CPC H10B 12/488; H10B 12/02; H10B 12/315; H10B 12/50

(57) ABSTRACT

A semiconductor device includes a substrate having a cell active region; a word line on the cell active region; a bit line electrically connected to the cell active region; a connection structure in the word line; and a word line contact plug in contact with the connection structure. The word line may include a gate electrode, and the connection structure may be disposed on the gate electrode. The connection structure and the gate electrode may include different materials from each other.

### CROSS-REFERENCE TO RELATED APPLICATIONS

This U.S. non-provisional patent application claims priority under 35 U.S.C. § 119 to Korean Patent Application No. 10-2023-0030718, filed on Mar. 8, 2023, in the Korean Intellectual Property Office, the entire contents of which are hereby incorporated by reference.

### BACKGROUND

### 1. Field

The present disclosure relates to a semiconductor, and in particular, to a semiconductor device including a device isolation pattern.

### 2. Description of the Related Art

Due to their small-sized, multifunctional, and/or low-cost characteristics, semiconductor devices are being esteemed as important elements in the electronics industry. The semiconductor devices are classified into semiconductor memory devices for storing data, semiconductor logic devices for processing data, and hybrid semiconductor devices including both memory and logic elements.

Due to the recent increasing demand for electronic devices with a fast speed and/or low power consumption, the semiconductor devices require a fast operating speed and/or a low operating voltage. Therefore, it is necessary to increase an integration density of the semiconductor devices. As the integration density of the semiconductor devices increases, a process failure may be increased in a process of fabricating the semiconductor devices. Thus, many studies are conducted to reduce the process failure in the fabrication process.

### SUMMARY

According to an embodiment, a semiconductor device may include a substrate including a cell active region, a word line on the cell active region, a bit line electrically connected to the cell active region, a connection structure in the word line, and a word line contact plug in contact with the connection structure. The word line may include a gate electrode, and the connection structure may be disposed on the gate electrode. The connection structure and the gate electrode may include different materials from each other.

According to an embodiment, a semiconductor device may include a substrate including a cell active region, a word line on the cell active region, a bit line electrically connected to the cell active region, a connection structure in the word line, and a word line contact plug in contact with the connection structure. The word line may include a gate electrode, a gate intervening pattern on the gate electrode, and a gate capping pattern on the gate intervening pattern. A level of a top surface of the connection structure may be higher than a level of a top surface of the gate intervening pattern.

According to an embodiment, a semiconductor device may include a substrate including a cell region, a peripheral region, and a boundary region between the cell region and the peripheral region, a cell active pattern on the boundary region, a boundary device isolation pattern defining the cell active pattern, a word line on the cell active pattern, a connection structure, a word line contact plug connected to the connection structure, and an interlayer insulating layer enclosing the word line contact plug. The word line may include a gate dielectric pattern on the cell active pattern, a gate electrode on the gate dielectric pattern, a gate intervening pattern on the gate electrode, and a gate capping pattern on the gate intervening pattern. The connection structure may electrically connect the gate electrode to the word line contact plug, and a side surface of the connection structure may be in contact with the gate dielectric pattern. The connection structure and the gate electrode may include different materials from each other, and the connection structure and the gate electrode may be provided to have an interface defined therebetween.

### BRIEF DESCRIPTION OF THE DRAWINGS

Features will become apparent to those of skill in the art by describing in detail exemplary embodiments with reference to the attached drawings, in which:

FIG. 1 is a block diagram illustrating a semiconductor device according to an embodiment.

FIG. 2 is an enlarged plan view illustrating portion P1 of FIG. 1.

FIG. 3A is a sectional view taken along lines A-A′, B-B′, and C-C′ of FIG. 2.

FIG. 3B is a sectional view taken along a line D-D′ of FIG. 2.

FIG. 4 is a sectional view along the line B-B′ of FIG. 2 of a semiconductor device according to an embodiment.

FIG. 5 is a sectional view along the line B-B′ of FIG. 2 of a semiconductor device according to an embodiment.

FIGS. 6 to 9 are sectional views illustrating stages in a method of fabricating a semiconductor device according to an embodiment.

FIGS. 10 to 12 are sectional views illustrating stages in a method of fabricating a semiconductor device according to an embodiment.

FIGS. 13 to 17 are sectional views illustrating stages in a method of fabricating a semiconductor device according to an embodiment.

FIGS. 18 to 22 are sectional views illustrating stages in a method of fabricating a semiconductor device according to an embodiment.

### DETAILED DESCRIPTION

Example embodiments will now be described more fully with reference to the accompanying drawings, in which example embodiments are shown.

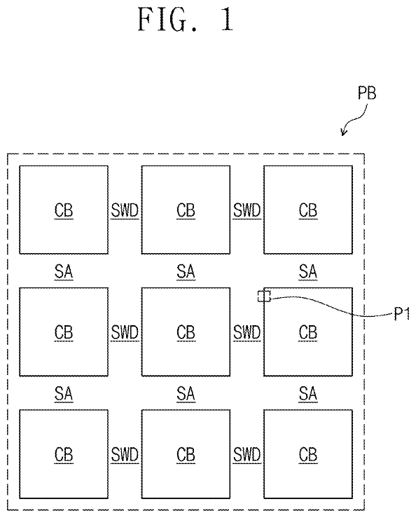

FIG. 1 is a block diagram illustrating a semiconductor device according to an embodiment.

Referring to FIG. 1, a semiconductor device may include cell blocks CB and a peripheral block PB, which is provided near or around each of the cell blocks CB. Each of the cell blocks CB may include a cell circuit, e.g., a memory integrated circuit. The peripheral block PB may include various peripheral circuits, which are used to operate the cell circuit, and the peripheral circuits may be electrically connected to the cell circuit.

The peripheral block PB may include sense amplifier circuits SA and sub-word line driver circuits SWD. In an embodiment, the sense amplifier circuits SA may be provided to face each other with the cell blocks CB interposed therebetween, and the sub-word line driver circuits SWD may be provided to face each other with the cell blocks CB interposed therebetween. For example, the peripheral block PB may further include power and ground circuits for driving a sense amplifier.

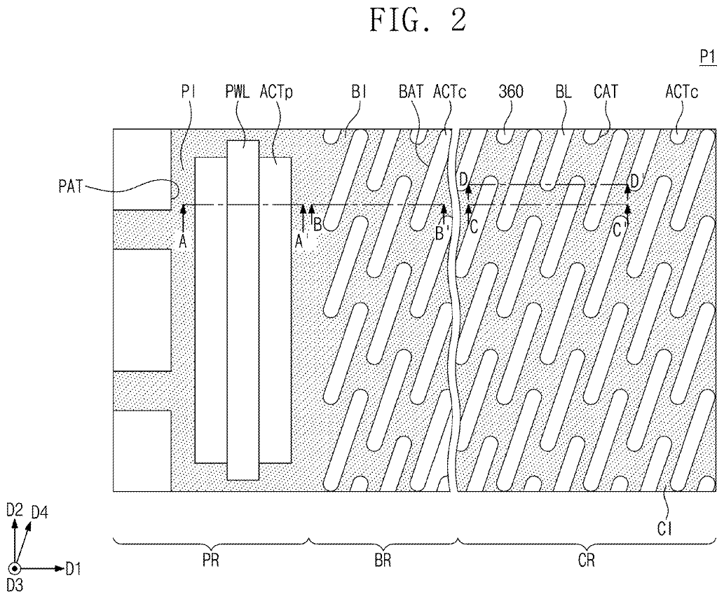

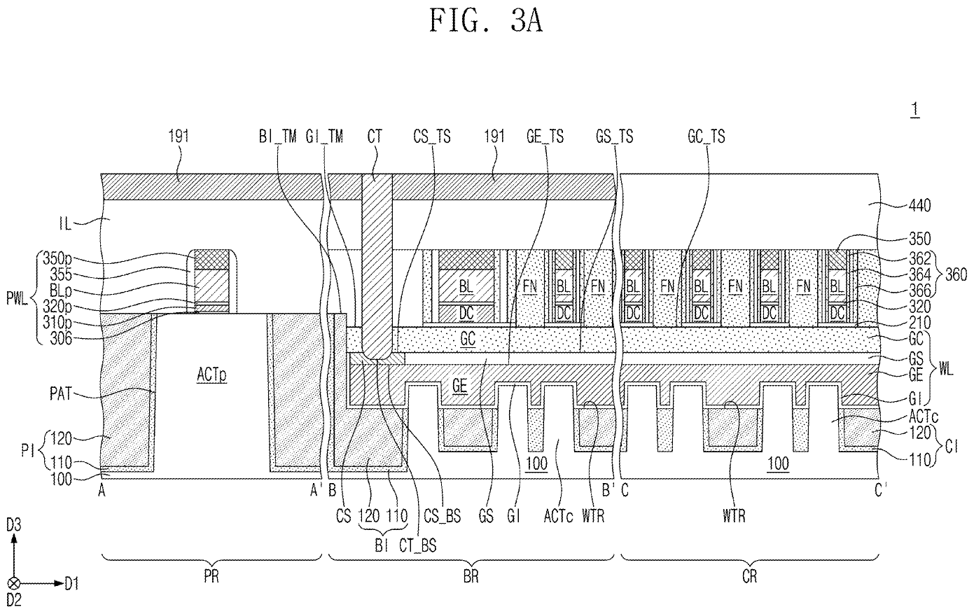

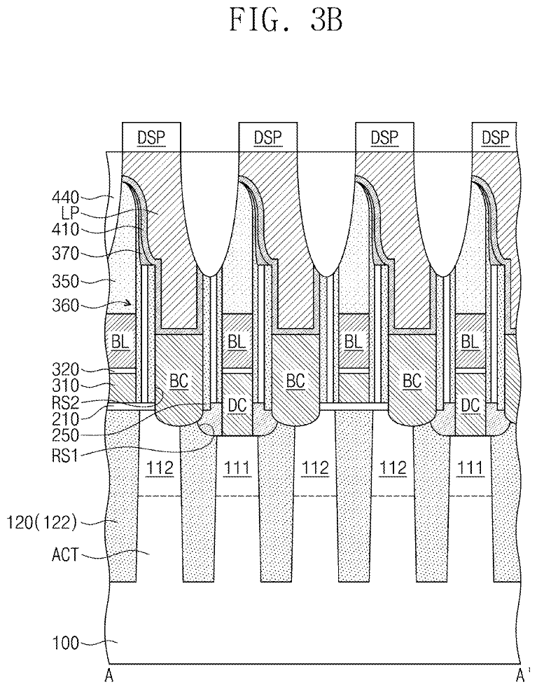

FIG. 2 is an enlarged plan view illustrating portion P1 of FIG. 1 of a semiconductor device according to an embodiment. FIG. 3A is a sectional view taken along lines A-A′, B-B′, and C-C′ of FIG. 2, and FIG. 3B is a sectional view taken along line D-D′ of FIG. 2.

Referring to FIGS. 2, 3A, and 3B, a semiconductor device 1 according to an embodiment may include a substrate 100. In an embodiment, the substrate 100 may include a cell region CR, a peripheral region PR, and a boundary region BR therebetween. The cell region CR may be a region of the substrate 100, in which the cell blocks CB of FIG. 1 are provided. The peripheral region PR may be another region of the substrate 100, in which the peripheral block PB of FIG. 1 is provided. The boundary region BR may be yet another region of the substrate 100 provided between each cell block CB and the peripheral block PB of FIG. 1.

A device isolation pattern may be located on the substrate 100. For example, the device isolation pattern may be placed in a trench region provided on the substrate 100. The device isolation pattern may include a cell device isolation pattern CI on the cell region CR, a peripheral device isolation pattern PI on the peripheral region PR, and a boundary device isolation pattern BI on the boundary region BR. The cell device isolation pattern CI may be disposed in a cell trench region CAT, which is provided on the cell region CR to define cell active patterns ACTc. The peripheral device isolation pattern PI may be disposed in a peripheral trench region PAT, which is provided on the peripheral region PR to define peripheral active patterns ACTp. The boundary device isolation pattern BI may be disposed in a boundary trench region BAT, which is provided on the boundary region BR and between the cell and peripheral active patterns ACTc and ACTp. For example, the cell active patterns ACTc on the boundary region BR may serve as dummy cell active patterns.

Each of the cell and peripheral active patterns ACTc and ACTp may include a portion of the substrate 100 enclosed by the device isolation pattern. In the present specification, for convenience of explanation, the substrate 100 may be regarded as the remaining portion of the substrate 100, except for the portion of the substrate 100 (i.e., the cell and peripheral active patterns ACTc and ACTp), unless otherwise specified.

The cell active patterns ACTc may be spaced apart from each other in a first direction D1 and a second direction D2. The first direction D1 and the second direction D2 may be parallel to a bottom surface of the substrate 100 and may be non-parallel (e.g., orthogonal) to each other. The cell and peripheral active patterns ACTc and ACTp may have a shape protruding in a third direction D3 perpendicular to the bottom surface of the substrate 100. Each of the cell active patterns ACTc may have a shape elongated in a fourth direction D4.

Each of the device isolation patterns may include at least one of a first device isolation layer 110 or a second device isolation layer 120. Each of the first and second device isolation layers 110 and 120 may be independently formed of or include, e.g., silicon oxide or silicon nitride. As an example, the first and second device isolation layers 110 and 120 may be formed of or include respective materials different from each other. For example, the second device isolation layer 120 may be formed of or include a material having a good gap-fill property (e.g., Tonen SilaZene (TOSZ)). The first device isolation layer 110 may be formed by a deposition process (e.g., an atomic layer deposition (ALD) process and so forth). As an example, the first and second device isolation layers 110 and 120 may be connected to each other without any interface therebetween. Alternatively, the first and second device isolation layers 110 and 120 may be provided as two separate layers, distinguishable by an interface between them. The structure or elements in each of the device isolation patterns may vary depending on widths of the cell, peripheral, and boundary trench regions CAT, PAT, and BAT and thicknesses of the first and second device isolation layers 110 and 120.

Hereinafter, features and element of the semiconductor device, which is provided in each of the cell, peripheral, and boundary regions CR, PR, and BR, will be described in more detail below for each respective region.

Referring to FIGS. 2, 3A, and 3B, the semiconductor device 1 may include the peripheral region PR, the cell region CR, and the boundary region BR.

The peripheral region PR may include the peripheral active pattern ACTp on the substrate 100, a peripheral device isolation pattern PI defining the peripheral active pattern ACTp, a peripheral word line PWL on the peripheral active pattern ACTp, an interlayer insulating layer IL on the peripheral word line PWL, and a conductive structure 191 in the interlayer insulating layer IL.

A level of a top surface of the peripheral active pattern ACTp may be equal to a level of a top surface of the peripheral device isolation pattern PI, e.g., relative to a bottom of the substrate 100. The peripheral active pattern ACTp may be defined by the peripheral device isolation pattern PI.

The peripheral device isolation pattern PI may be provided on the substrate 100. The peripheral device isolation pattern PI may include the first and second device isolation layers 110 and 120. The first and second device isolation layers 110 and 120 may be provided to sequentially cover an inner surface of the peripheral trench region PAT. The first device isolation layer 110 may conformally cover the inner surface of the peripheral trench region PAT. The second device isolation layer 120 may be provided on the first device isolation layer 110 to fill the remaining portion of the peripheral trench region PAT.

The peripheral word line PWL may be disposed on the peripheral active pattern ACTp. The peripheral active pattern ACTp may include a pair of impurity regions formed therein, and the peripheral word line PWL may be placed between the pair of impurity regions, when viewed in a plan view. The peripheral word line PWL may include a plurality of patterns, which are sequentially stacked on the peripheral active pattern ACTp, and peripheral spacers, which are formed to cover opposite side surfaces of the stacked patterns. As an example, the peripheral word line PWL may include a peripheral dielectric pattern 306, a peripheral intervening pattern 310p, a peripheral ohmic pattern 320p, a peripheral electrode pattern BLp, and a peripheral capping pattern 350p, which are sequentially stacked on the peripheral active pattern ACTp, and a pair of peripheral spacers 355 covering opposite side surfaces of the resultant stack.

The peripheral dielectric pattern 306 may be formed of or include at least one of, e.g., silicon oxide or high-k dielectric materials. The peripheral intervening pattern 310p, the peripheral ohmic pattern 320p, and the peripheral electrode pattern BLp may be formed of or include the same materials as an intervening pattern 310, a first ohmic pattern 320, and a bit line BL on the cell region CR, which will be described below. The peripheral capping pattern 350p may be formed of or include the same material as a bit line capping pattern 350, which will be described below. The peripheral spacer 355 may be formed of or include at least one of, e.g., silicon oxide or silicon nitride and may be a single layer or a composite layer.

The interlayer insulating layer IL may be provided on the peripheral region PR to cover the peripheral active pattern ACTp, the peripheral device isolation pattern PI, and the peripheral word line PWL. The interlayer insulating layer IL may further cover the boundary device isolation pattern BI, on the boundary region BR.

The interlayer insulating layer IL may be formed of or include an insulating material. For example, the interlayer insulating layer IL may be formed of or include at least one of, e.g., silicon oxide, silicon nitride, TEOS, or low-k dielectric materials. In an embodiment, the interlayer insulating layer IL may be a single layer, which is made of a single material, or a composite layer including two or more materials. For example, conductive structures may be provided to penetrate the interlayer insulating layer IL and may be electrically connected to at least one of the peripheral active pattern ACTp or the peripheral word line PWL.

The conductive structures 191 may be provided in the interlayer insulating layer IL. The conductive structures 191 may include a conductive material. The conductive structure 191 may include a peripheral conductive contact electrically connected to the peripheral active pattern ACTp.

The cell region CR may include the cell active pattern ACTc on the substrate 100, the cell device isolation pattern CI defining the cell active pattern ACTc, a word line WL on the cell active pattern ACTc, a bit line contact DC, the first ohmic pattern 320 on the bit line contact DC, the bit line BL on the first ohmic pattern 320, the bit line capping pattern 350 on the bit line BL, a bit line spacer 360 on a side surface of the bit line BL, and a filler pattern 440 on the bit line capping pattern 350.

A level of a top surface of the cell active pattern ACTc may be lower than the level of the top surface of the peripheral active pattern ACTp, e.g., relative to a bottom of the substrate 100. The cell active pattern ACTc may be defined by the cell device isolation pattern CI.

The cell device isolation pattern CI may be provided on the substrate 100. The cell device isolation pattern CI may include the first and second device isolation layers 110 and 120. The first and second device isolation layers 110 and 120 may be provided to sequentially cover an inner surface of the cell trench region CAT. The first device isolation layer 110 may conformally cover the inner surface of the cell trench region CAT. The second device isolation layer 120 may be provided on the first device isolation layer 110 to fill the remaining portion of the cell trench region CAT.

The word line WL may be disposed to cross the cell active patterns ACTc. In an embodiment, a plurality of word lines WL may be provided. The word lines WL may be extended in the first direction D1 and may be spaced apart from each other in the second direction D2. The word lines WL may be disposed in word line trenches WTR, which are formed in the cell active patterns ACTc, the cell device isolation pattern CI, and the boundary device isolation pattern BI. In an embodiment, a pair of word line WL, which are adjacent to each other in the second direction D2, may be provided to cross a plurality of cell active patterns ACTc arranged in the first direction D1.

Each of the word lines WL may include a gate electrode GE, a gate dielectric pattern GI, a gate intervening pattern GS, and a gate capping pattern GC. The gate electrode GE may penetrate the cell active patterns ACTc and the cell device isolation pattern CI in the first direction D1. The gate dielectric pattern GI may be interposed between the gate electrode GE and the cell active patterns ACTc, and between the gate electrode GE and the cell device isolation pattern CI. The gate intervening pattern GS may be provided on the gate electrode GE to cover a top surface of the gate electrode GE. The gate capping pattern GC may be provided on the gate intervening pattern GS to cover a top surface of the gate intervening pattern GS. The gate intervening pattern GS may be formed of or include, e.g., polysilicon. The gate electrode GE may be formed of or include a conductive material. The gate dielectric pattern GI may be formed of or include at least one of, e.g., silicon oxide or high-k dielectric materials. The gate capping pattern GC may be formed of or include, e.g., silicon nitride.

A buffer pattern 210 may be disposed on the substrate 100. The buffer pattern 210 may cover the cell active patterns ACTc, the cell device isolation pattern CI, and the word lines WL. The buffer pattern 210 may be formed of or include, e.g., at least one of silicon oxide, silicon nitride, silicon oxynitride, or combinations thereof. The buffer pattern 210 may be a single layer, which is made of a single material, or a composite layer including two or more materials.

The bit line contact DC may be provided on each of the cell active patterns ACTc, and in an embodiment, a plurality of bit line contacts DC may be provided. The bit line contacts DC may be electrically connected to the cell active patterns ACTc, respectively. The bit line contacts DC may be spaced apart from each other in the first and second directions D1 and D2. The bit line contacts DC may be respectively interposed between the cell active patterns ACTc and the bit lines BL.

A gap-fill insulating pattern 250 may be provided. The gap-fill insulating pattern 250 may cover at least a portion of a side surface of the bit line contact DC. The gap-fill insulating pattern 250 may be formed of or include at least one of, e.g., silicon oxide, silicon nitride, or combinations thereof. The gap-fill insulating pattern 250 may be a single layer, which is made of a single material, or a composite layer including two or more materials.

The bit line BL may be provided on the bit line contact DC. The bit line BL may be extended in the second direction D2. The bit line BL may be disposed on the bit line contacts DC, which are arranged in the second direction D2 to form a line. In an embodiment, a plurality of bit lines BL may be provided. The bit lines BL may be spaced apart from each other in the first direction D1. The bit line BL may be formed of or include at least one of metallic materials. As an example, the bit line BL may be formed of or include at least one of, e.g., tungsten, rubidium, molybdenum, titanium, or combinations thereof.

The intervening pattern 310 may be provided between the bit line BL and the buffer pattern 210. In an embodiment, a plurality of intervening patterns 310 may be provided. The intervening pattern 310 may have a top surface that is located at a substantially same height as (i.e., coplanar with) a top surface of the bit line contact DC. The intervening pattern 310 may be formed of or include, e.g., doped polysilicon.

The first ohmic pattern 320 may be interposed between the bit line BL and the bit line contact DC. The first ohmic pattern 320 may be extended along the bit line BL and in the second direction D2. In an embodiment, a plurality of first ohmic patterns 320 may be provided. The first ohmic patterns 320 may be spaced apart from each other in the first direction D1. The first ohmic pattern 320 may be formed of or include, e.g., a metal silicide material. A first barrier pattern may be further interposed between the bit line BL and the bit line contact DC. The first barrier pattern may be formed of or include at least one of conductive metal nitride materials (e.g., titanium nitride and tantalum nitride).

The bit line capping pattern 350 may be provided on a top surface of the bit line BL. On the top surface of the bit line BL, the bit line capping pattern 350 may be extended in the second direction D2. In an embodiment, a plurality of bit line capping patterns 350 may be provided. The bit line capping patterns 350 may be spaced apart from each other in the first direction D1. The bit line capping pattern 350 may be vertically overlapped with the bit line BL. The bit line capping pattern 350 may be composed of a single layer or a plurality of layers.

The bit line spacer 360 may be provided on a side surface of the bit line BL and a side surface of the bit line capping pattern 350. The bit line spacer 360 may cover the side surface of the bit line BL and the side surface of the bit line capping pattern 350. The bit line spacer 360 may be extended along the side surface of the bit line BL and in the second direction D2.

The bit line spacer 360 may include a plurality of spacers. As an example, the bit line spacer 360 may include a first spacer 362, a second spacer 364, and a third spacer 366. The third spacer 366 may be provided on the side surface of the bit line BL and the side surface of the bit line capping pattern 350. The first spacer 362 may be interposed between a storage node contact BC, which will be described below, and the third spacer 366. The second spacer 364 may be interposed between the first spacer 362 and the third spacer 366. In an embodiment, each of the first to third spacers 362, 364, and 366 may be independently formed of or include at least one of, e.g., silicon nitride, silicon oxide, silicon oxynitride, or combinations thereof. In another embodiment, the second spacer 364 may include an air gap separating the first and third spacers 362 and 366 from each other.

A capping spacer 370 may be placed on the bit line spacer 360. The capping spacer 370 may cover an upper portion of a side surface of the bit line spacer 360. In an embodiment, the capping spacer 370 may be formed of or include, e.g., silicon nitride.

The storage node contact BC may be provided between adjacent ones of the bit lines BL. As an example, the storage node contact BC may be interposed between adjacent ones of the bit line spacers 360. In an embodiment, a plurality of storage node contacts BC may be provided. The storage node contacts BC may be spaced apart from each other in the first and second directions D1 and D2 by fence patterns FN. The storage node contacts BC may be spaced apart from each other in the second direction D2 by the fence patterns FN on the word lines WL. The fence pattern FN may be provided between adjacent ones of the bit lines BL. In an embodiment, a plurality of fence patterns FN may be provided. The fence patterns FN may be spaced apart from each other in the first and second directions D1 and D2. The fence patterns FN, which are adjacent to each other in the first direction D1, may be spaced apart from each other, with the bit line BL interposed therebetween. The fence patterns FN, which are adjacent to each other in the second direction D2, may be spaced apart from each other, with the storage node contact BC interposed therebetween.

In an embodiment, the fence patterns FN may be formed of or include, e.g., silicon nitride. The storage node contact BC may be formed of or include at least one of, e.g., doped or undoped polysilicon, metallic materials, or combinations thereof.

A second barrier pattern 410 may conformally cover the bit line spacer 360, the fence pattern FN, and the storage node contact BC. The second barrier pattern 410 may be formed of or include metal nitride materials (e.g., titanium nitride and tantalum nitride). A second ohmic pattern may be further interposed between the second barrier pattern 410 and the storage node contact BC. The second ohmic pattern may be formed of or include a metal silicide material.

A landing pad LP may be provided on the storage node contact BC. In an embodiment, a plurality of landing pads LP may be provided.

Each of the landing pads LP may be connected to a corresponding one of the storage node contacts BC. The landing pad LP may cover a top surface of the bit line capping pattern 350. A lower region of the landing pad LP may be vertically overlapped with the storage node contact BC. The landing pad LP may be formed of or include at least one of metallic materials (e.g., tungsten, titanium, and tantalum).

The filler pattern 440 may conformally cover the bit line spacer 360, the fence pattern FN, and the storage node contact BC. As an example, the filler pattern 440 may be formed of or include at least one of, e.g., silicon nitride, silicon oxide, silicon oxynitride, or combinations thereof. Alternatively, the filler pattern 440 may include an empty space with an air layer (i.e., an air gap).

The conductive structure 191 may be provided in the filler pattern 440. The conductive structure 191 may be extended in a direction parallel to the gate capping pattern GC. The conductive structure 191 may be connected to a word line contact plug CT, which will be described below. The conductive structure 191 may include a conductive material. The conductive structure 191 and the word line contact plug CT may form a single object, e.g., a single and integral body, without any interface therebetween.

A data storage pattern DSP may be provided on the landing pad LP. In an embodiment, a plurality of data storage patterns DSP may be provided. In an embodiment, the data storage pattern DSP may be a capacitor including a bottom electrode, a dielectric layer, and a top electrode. In this case, the semiconductor memory device according to an embodiment may be a dynamic random access memory (DRAM) device. In an embodiment, the data storage pattern DSP may include a magnetic tunnel junction pattern. In this case, the semiconductor memory device may be a magnetic random access memory (MRAM) device. In an embodiment, the data storage pattern DSP may be formed of or include a phase-change material or a variable resistance material. In this case, the semiconductor memory device may be a phase-change random access memory (PRAM) device or a resistive random access memory (ReRAM) device. For example, the data storage pattern DSP may include various structures and/or materials which can be used to store data.

The boundary region BR may include the cell active pattern ACTc and a boundary device isolation pattern BI on the substrate 100, the word line WL on the cell active pattern ACTc, a connection structure CS in the word line WL, the word line contact plug CT on the connection structure CS, and the interlayer insulating layer IL enclosing the word line contact plug CT.

The cell active pattern ACTc in the boundary region BR may be defined by the boundary device isolation pattern BI. The cell active pattern ACTc in the boundary region BR may be, e.g., a dummy active region.

The boundary device isolation pattern BI may be provided on the substrate 100. The boundary device isolation pattern BI may include the first and second device isolation layers 110 and 120. The first and second device isolation layers 110 and 120 may be provided to sequentially cover an inner surface of the boundary trench region BAT. The first device isolation layer 110 may conformally cover the inner surface of the boundary trench region BAT. The second device isolation layer 120 may be provided on the first device isolation layer 110 to fill the remaining portion of the boundary trench region BAT.

In an embodiment, the word line WL may be provided on the cell active pattern ACTc in the boundary region BR. The word line WL in the boundary region BR may be, e.g., continuously, extended from the cell region CR. The word line WL may include the gate electrode GE, the gate dielectric pattern GI, the gate intervening pattern GS, and the gate capping pattern GC.

The connection structure CS may be provided on the gate electrode GE, e.g., the connection structure CS may be directly on the gate electrode GE within the word line WL. The connection structure CS may be formed of or include a conductive material. The connection structure CS may be provided to penetrate the gate intervening pattern GS. A top surface of the connection structure CS may be in, e.g., direct, contact with the gate capping pattern GC. A first side surface of the connection structure CS may be in, e.g., direct, contact with the gate intervening pattern GS. A second side surface of the connection structure CS may be in, e.g., direct, contact with the gate dielectric pattern GI. The gate electrode GE and the connection structure CS may be formed of or include different conductive materials from each other. A lattice constant of the gate electrode GE may be different from a lattice constant of the connection structure CS. The connection structure CS may be overlapped with the boundary device isolation pattern BI. In an embodiment, the connection structure CS may not be, e.g., vertically and/or horizontally, overlapped with the cell active pattern ACTc. The connection structure CS may have an electric conductivity higher than that of the gate electrode GE.

The word line contact plug CT may be provided on the connection structure CS, e.g., the connection structure CS may be between the word line contact plug CT and the gate electrode GE in the vertical direction (e.g., the third direction DR3). The word line contact plug CT may be electrically connected to the connection structure CS. The word line contact plug CT may be formed of or include a conductive material. The largest width of the word line contact plug CT may be smaller than the largest width of the connection structure CS, e.g., in the first direction D1.

The gate capping pattern GC may be provided on the connection structure CS and the gate intervening pattern GS. The gate capping pattern GC may enclose the word line contact plug CT, e.g., the gate capping pattern GC may surround a perimeter of the word line contact plug CT. The word line contact plug CT may be provided to penetrate the gate capping pattern GC.

The interlayer insulating layer IL may be provided on the gate capping pattern GC. The interlayer insulating layer IL may enclose, e.g., surround a perimeter of, the word line contact plug CT. The gate capping pattern GC and the boundary device isolation pattern BI may be provided to form a staircase structure. For example, as illustrated in FIG. 3A, the connection structure CS may extend above the top surface of the gate electrode GE, so the connection structure CS with the gate electrode GE may have a staircase structure defined by the boundary device isolation pattern BI and the gate capping pattern GC with the gate intervening pattern GS.

A level of a top surface GE_TS of the gate electrode GE may be lower than a level of a bottom surface CT_BS of the word line contact plug CT, e.g., relative to the bottom of the substrate 100. The bottom surface CT_BS of the word line contact plug CT may be in, e.g., direct, contact with the connection structure CS. A level of the bottom surface CT_BS of the word line contact plug CT may be higher than the level of the top surface GE_TS of the gate electrode GE and may be lower than a level of a top surface CS_TS of the connection structure CS, e.g., relative to the bottom of the substrate 100. The level of the bottom surface CT_BS of the word line contact plug CT may be lower than a level of the top surface of the gate intervening pattern GS, e.g., relative to the bottom of the substrate 100. The level of the top surface CS_TS of the connection structure CS may be equal to (e.g., coplanar with) a level of a top surface GS_TS of the gate intervening pattern GS. The level of the top surface CS_TS of the connection structure CS may be lower than a level of a top surface GC_TS of the gate capping pattern GC, e.g., relative to the bottom of the substrate 100. The level of the top surface GC_TS of the gate capping pattern GC may be equal to a level of a topmost surface of the gate dielectric pattern GI, e.g., relative to the bottom of the substrate 100. A level of the topmost surface BI_TM of the boundary device isolation pattern BI may be higher than the level of the top surface GC_TS of the gate capping pattern GC, e.g., relative to the bottom of the substrate 100. The level of the top surface GC_TS of the gate capping pattern GC may be lower than the level of the topmost surface BI_TM of the boundary device isolation pattern BI, e.g., relative to the bottom of the substrate 100.

The top surface CS_TS of the connection structure CS may be coplanar with the top surface GS_TS of the gate intervening pattern GS. A bottom surface of the connection structure CS may be coplanar with the top surface GE_TS of the gate electrode GE.

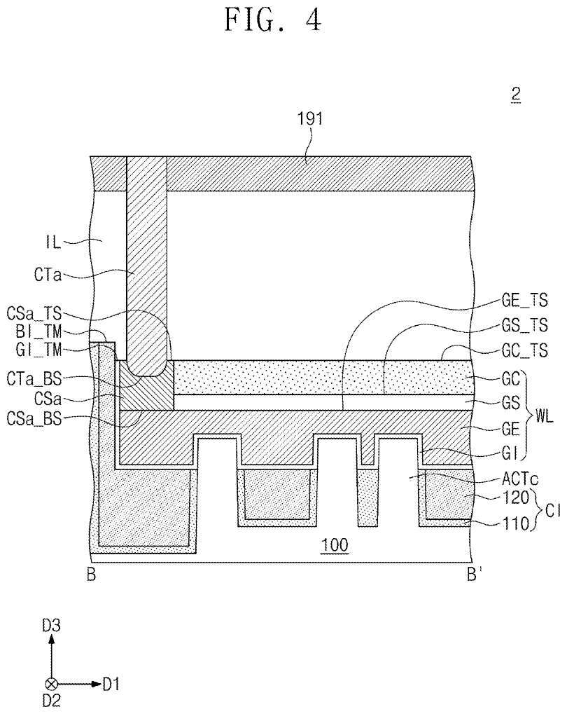

FIG. 4 is an enlarged sectional view, which is taken along the line B-B′ of FIG. 2 to illustrate a semiconductor device according to an embodiment.

Referring to FIG. 4, a semiconductor device 2 may include the substrate 100, the cell active pattern ACTc on the substrate 100, the boundary device isolation pattern BI defining the cell active pattern ACTc, the word line WL on the cell active pattern ACTc, a connection structure CSa in the word line WL, the interlayer insulating layer IL on the connection structure CSa and the word line WL, and a word line contact plug CTa on the connection structure CSa, in the boundary region BR. In the following description, a previously-described element may be identified by the same reference number without repeating an overlapping description thereof, for concise description.

The word line WL may include the gate dielectric pattern GI, the gate electrode GE, the gate intervening pattern GS, and the gate capping pattern GC.

The connection structure CSa may be provided on the gate electrode GE. The connection structure CSa may be provided to penetrate the gate intervening pattern GS and the gate capping pattern GC.

A side surface of the connection structure CSa may be in contact with the gate intervening pattern GS and the gate capping pattern GC. Another side surface of the connection structure CSa may be in contact with the gate dielectric pattern GI.

A level of a bottom surface CSa_BS of the connection structure CSa may be equal to (e.g., coplanar with) the level of the top surface GE_TS of the gate electrode GE. A level of a top surface CSa_TS of the connection structure CSa may be higher than the level of the top surface GS_TS of the gate intervening pattern GS, e.g., relative to the bottom of the substrate 100. The level of the top surface CSa_TS of the connection structure CSa may be lower than the level of the topmost surface BI_TM of the boundary device isolation pattern BI, e.g., relative to the bottom of the substrate 100. The level of the top surface CSa_TS of the connection structure CSa may be equal to (e.g., coplanar with) the level of the top surface GC_TS of the gate capping pattern GC. The level of the top surface CSa_TS of the connection structure CSa may be equal to (e.g., coplanar with) a level of the topmost surface GI_TM of the gate dielectric pattern GI.

A level of a bottom surface CTa_BS of the word line contact plug CTa may be higher than the level of the top surface GS_TS of the gate intervening pattern GS and may be lower than the level of the top surface CSa_TS of the connection structure CSa, e.g., relative to the bottom of the substrate 100. The level of the bottom surface CTa_BS of the word line contact plug CTa may be lower than the level of the topmost surface GI_TM of the gate dielectric pattern GI, e.g., relative to the bottom of the substrate 100.

A bottom surface of the connection structure CSa may be coplanar with a bottom surface of the gate intervening pattern GS. The bottom surface of the connection structure CSa may be coplanar with the top surface of the gate electrode GE. The top surface CSa_TS of the connection structure CSa may be coplanar with the top surface GC_TS of the gate capping pattern GC.

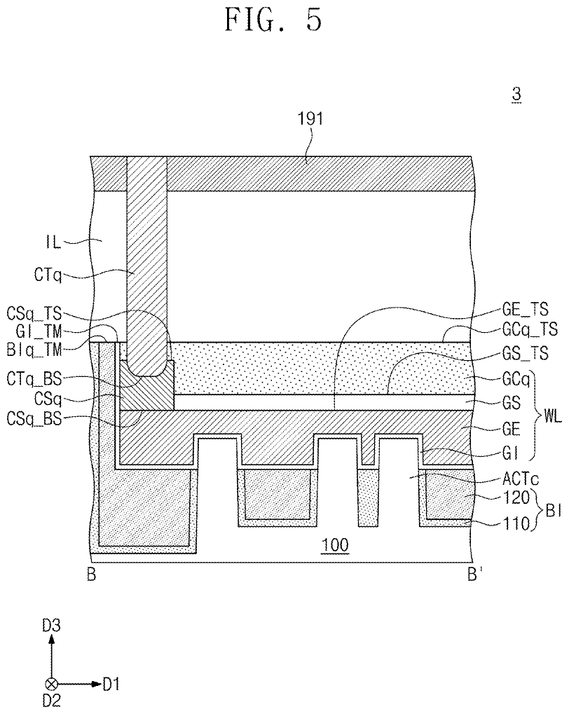

FIG. 5 is a sectional view, which is taken along the line B-B′ of FIG. 2 to illustrate a semiconductor device according to an embodiment.

Referring to FIG. 5, a semiconductor device 3 may include the substrate 100, the cell active pattern ACTc on the substrate 100, the boundary device isolation pattern BI defining the cell active pattern ACTc, the word line WL on the cell active pattern ACTc, a connection structure CSq in the word line WL, the interlayer insulating layer IL on the word line WL, and a word line contact plug CTq on the connection structure CSa, in the boundary region BR. In the following description, a previously-described element may be identified by the same reference number without repeating an overlapping description thereof, for concise description.

The word line WL may include the gate dielectric pattern GI, the gate electrode GE, the gate intervening pattern GS, and a gate capping pattern GCq.

The connection structure CSq may be provided on the gate electrode GE. The connection structure CSq may be provided to penetrate the gate intervening pattern GS. The gate capping pattern GCq may cover the connection structure CSq.

A side surface of the connection structure CSq may be in contact with the gate intervening pattern GS and the gate capping pattern GCq. Another side surface of the connection structure CSq may be in contact with the gate dielectric pattern GI.

A level of a bottom surface CSq_BS of the connection structure CSq may be equal to the level of the top surface GE_TS of the gate electrode GE. A level of a top surface CSq_TS of the connection structure CSq may be higher than the level of the top surface GE_TS of the gate electrode GE. The level of the top surface CSq_TS of the connection structure CSq may be higher than the level of the top surface GS_TS of the gate intervening pattern GS and may be lower than a level of a top surface GCq_TS of the gate capping pattern GCq.

A level of a bottom surface CTq_BS of the word line contact plug CTq may be higher than the level of the bottom surface CSq_BS of the connection structure CSq. The level of the bottom surface CTq_BS of the word line contact plug CTq may be lower than the level of the top surface CSq_TS of the connection structure CSq. The level of the bottom surface CTq_BS of the word line contact plug CTq may be higher than the level of the top surface GS_TS of the gate intervening pattern GS and may be lower than the level of the top surface GCq_TS of the gate capping pattern GCq. The level of the top surface GCq_TS of the gate capping pattern GCq may be equal to the level of the topmost surface GI_TM of the gate dielectric pattern GI. The level of the top surface GCq_TS of the gate capping pattern GCq may be equal to a level of a top surface BIa_TS of a boundary device isolation pattern BIq.

The bottom surface CSq_BS of the connection structure CSq may be coplanar with the top surface GE_TS of the gate electrode GE. The top surface GCq_TS of the gate capping pattern GCq may be coplanar with the top surface BIq_TS of the boundary device isolation pattern BIq and the topmost surface GI_TM of the gate dielectric pattern GI.

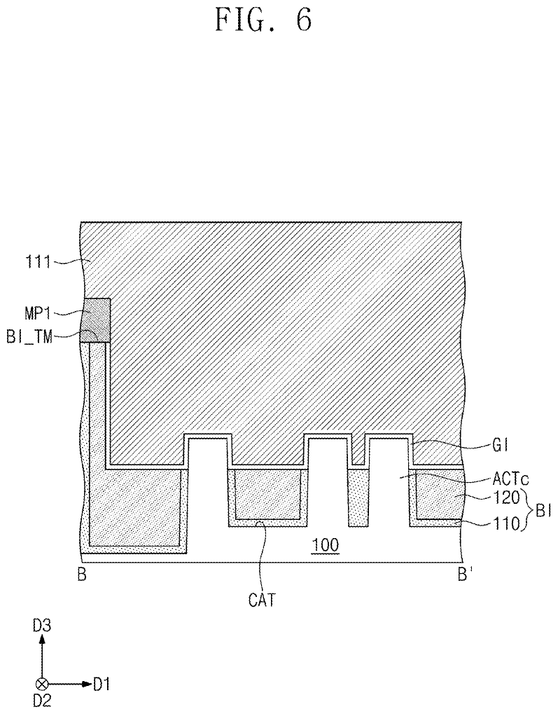

FIGS. 6 to 9 are sectional views illustrating stages in a method of fabricating a semiconductor device according to an embodiment.

Hereinafter, a method of fabricating the semiconductor device 1 taken along a line B-B′ of FIG. 3 will be described. As shown in FIG. 6, the cell active pattern ACTc may be formed on the substrate 100, the boundary device isolation pattern BI may be formed to define the cell active pattern ACTc, a first mask pattern MP1 and a preliminary gate electrode 111 may be formed on the boundary device isolation pattern BI, and the gate dielectric pattern GI may be formed between the preliminary gate electrode 111 and the boundary device isolation pattern BI and between the preliminary gate electrode 111 and the cell active pattern ACTc.

The cell trench region CAT may be formed by performing a patterning process on the substrate 100. The cell active patterns ACTc may be defined by the cell trench region CAT.

The patterning process may include forming mask patterns on the substrate 100 using an exposure process and etching the substrate 100 using the mask patterns as an etch mask. In an embodiment, the exposure process and the etching process may be alternately repeated several times. As an example, the exposure process may be an exposure process that is performed using extreme ultraviolet (EUV) light.

The boundary device isolation pattern BI may be formed on the cell trench region CAT. The boundary device isolation pattern BI may be formed by sequentially depositing the first and second device isolation layers 110 and 120 on the substrate 100 and etching the first and second device isolation layers 110 and 120.

First, the first device isolation layer 110 may be conformally deposited on the cell trench region CAT and the cell active patterns ACTc. Thereafter, the second device isolation layer 120 may be deposited on the first device isolation layer 110.

A patterning process may be performed on the first and second device isolation layers 110 and 120. As an example, the patterning process may be performed to remove upper portions of the first and second device isolation layers 110 and 120. The patterning process may be performed to leave the first and second device isolation layers 110 and 120 in the trench regions. The first and second device isolation layers 110 and 120 may have a position-dependent etch rate in the patterning process. For example, the etch rate of the first and second device isolation layers 110 and 120 may be lower near the peripheral region PR than near the cell region CR. As a result, the boundary device isolation pattern BI may be formed.

The gate dielectric pattern GI may be formed on the boundary device isolation pattern BI and the cell active patterns ACTc. The gate dielectric pattern GI may be conformally deposited on the boundary device isolation pattern BI and the cell active patterns ACTc.

The first mask pattern MP1 may be disposed on the boundary device isolation pattern BI close to the peripheral region PR. After the formation of the first mask pattern MP1, the preliminary gate electrode 111 may be formed. The preliminary gate electrode 111 may be formed of or include a conductive material.

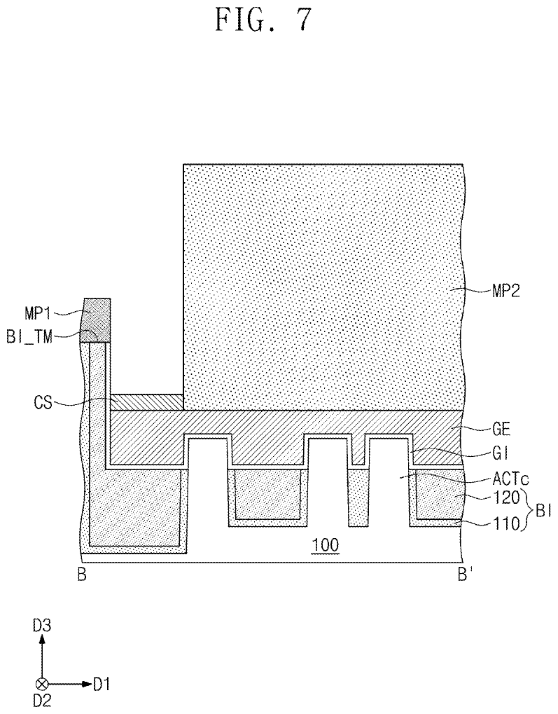

Referring to FIG. 7, the gate electrode GE may be formed by partially removing the preliminary gate electrode 111.

After the formation of the gate electrode GE, a second mask pattern MP2 may be formed on the gate electrode GE to expose a region, on which the connection structure CS will be formed. After the formation of the second mask pattern MP2, the connection structure CS may be formed by depositing a conductive material on the exposed region of the gate electrode GE. The deposition of the conductive material may be performed such that a top surface of the conductive material is located at a level lower than the topmost surface BI_TM of the boundary device isolation pattern BI.

Since the gate electrode GE and the connection structure CS are sequentially formed with a time interval, there may be an observable interface between the gate electrode GE and the connection structure CS. In an embodiment, the gate electrode GE and the connection structure CS may be formed of or include different materials from each other.

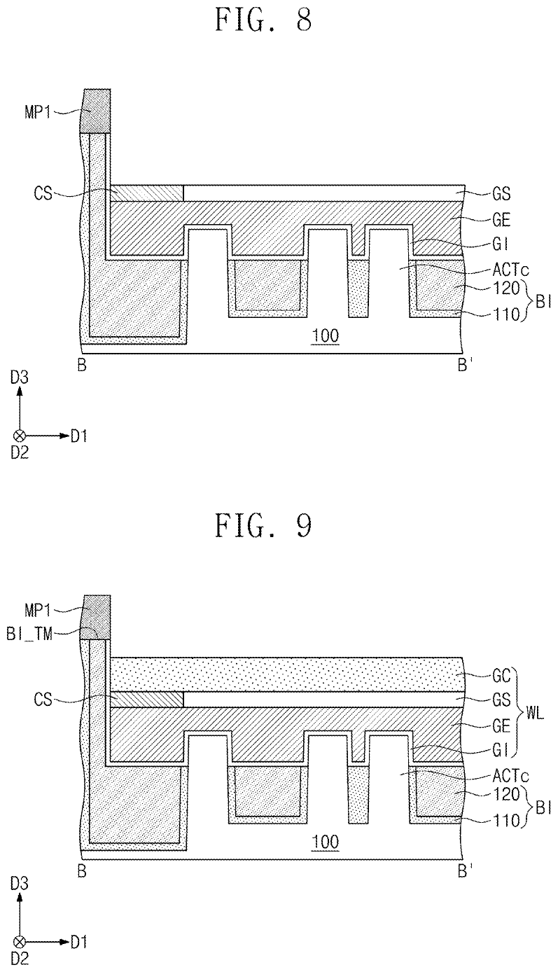

Referring to FIG. 8, the gate intervening pattern GS may be formed. The gate intervening pattern GS may be formed by performing a deposition process after removing the second mask pattern MP2. If the gate intervening pattern GS is deposited to cover the top surface of the connection structure CS, the gate intervening pattern GS may be partially removed such that the gate intervening pattern GS is locally left in a region lower than the top surface of the connection structure CS. The gate intervening pattern GS may be formed of or include, e.g., polysilicon.

Referring to FIG. 9, the gate capping pattern GC may be formed on the connection structure CS and the gate intervening pattern GS. The gate capping pattern GC may be formed to cover the top surface of the gate intervening pattern GS and the top surface of the connection structure CS. A level of a top surface of the gate capping pattern GC may be lower than the level of the topmost surface BI_TM of the boundary device isolation pattern BI. Since the gate capping pattern GC is formed in the presence of the first mask pattern MP1, the gate capping pattern GC may not be formed on the boundary device isolation pattern BI. The gate capping pattern GC may be used as a part of the word line WL.

After the formation of the gate capping pattern GC, the first mask pattern MP1 may be removed. Thereafter, the interlayer insulating layer IL may be deposited on the boundary device isolation pattern BI and the gate capping pattern GC. After the deposition of the interlayer insulating layer IL, the word line contact plug CT may be formed. The formation of the word line contact plug CT may include forming a trench to penetrate the interlayer insulating layer IL and the gate capping pattern GC and expose the connection structure CS and filling the trench with a conductive material. The conductive structure 191, which is electrically connected to the word line contact plug CT, may be formed. As a result of the afore-described process, the semiconductor device 1 of FIGS. 3A and 3B may be formed.

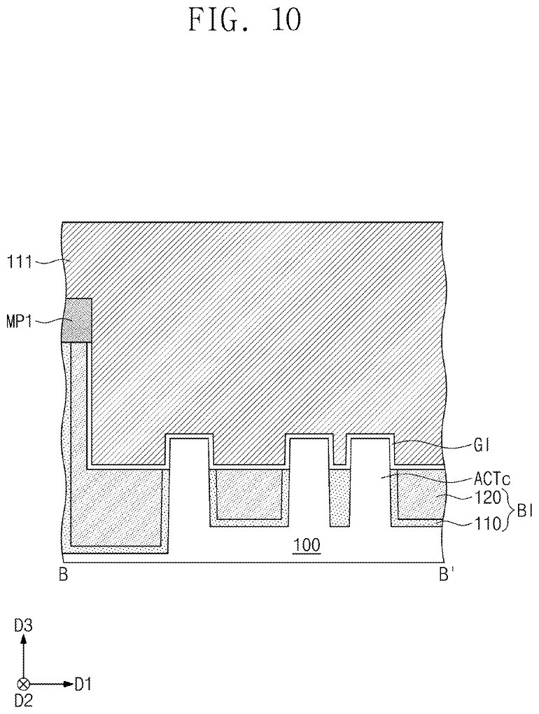

FIGS. 10 to 12 are sectional views illustrating stages in a method of fabricating a semiconductor device according to an embodiment. In the following description, a previously-described element may be identified by the same reference number without repeating an overlapping description thereof, for concise description.

Hereinafter, a method of fabricating the semiconductor device 2 taken along a line B-B′ of FIG. 4 will be described. As shown in FIG. 10, the cell active pattern ACTc may be formed on the substrate 100, the boundary device isolation pattern BI may be formed to define the cell active pattern ACTc, the first mask pattern MP1 and the preliminary gate electrode 111 may be formed on the boundary device isolation pattern BI, and the gate dielectric pattern GI may be formed between the preliminary gate electrode 111 and the boundary device isolation pattern BI, and between the preliminary gate electrode 111 and the cell active pattern ACTc.

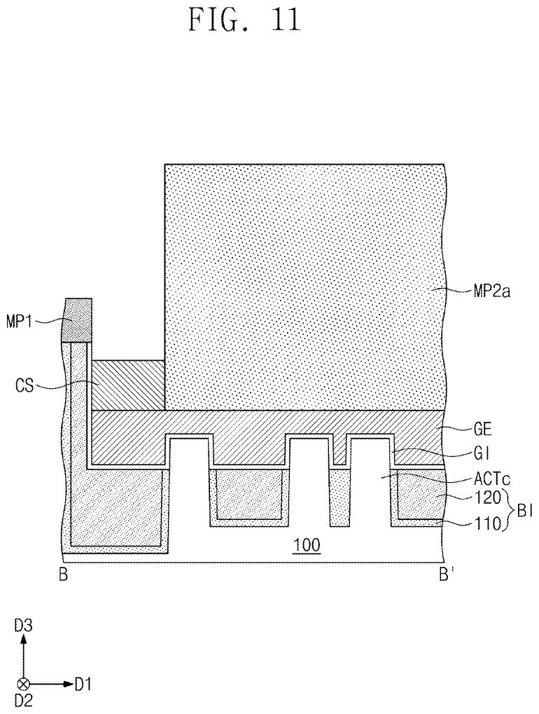

Referring to FIG. 11, the gate electrode GE may be formed by removing a portion of the preliminary gate electrode 111.

After the formation of the gate electrode GE, a second mask pattern MP2a may be formed on the gate electrode GE to expose a region, on which the connection structure CSa will be formed. After the formation of the second mask pattern MP2a, the connection structure CSa may be formed by depositing a conductive material on the exposed region of the gate electrode GE. The deposition of the conductive material may be performed such that a top surface of the conductive material is located to a level lower than the topmost surface BI_TM of the boundary device isolation pattern BI.

Since the gate electrode GE and the connection structure CSa are sequentially formed with a time interval, there may be an observable interface between the gate electrode GE and the connection structure CSa. The gate electrode GE and the connection structure CSa may be formed of or include different materials from each other.

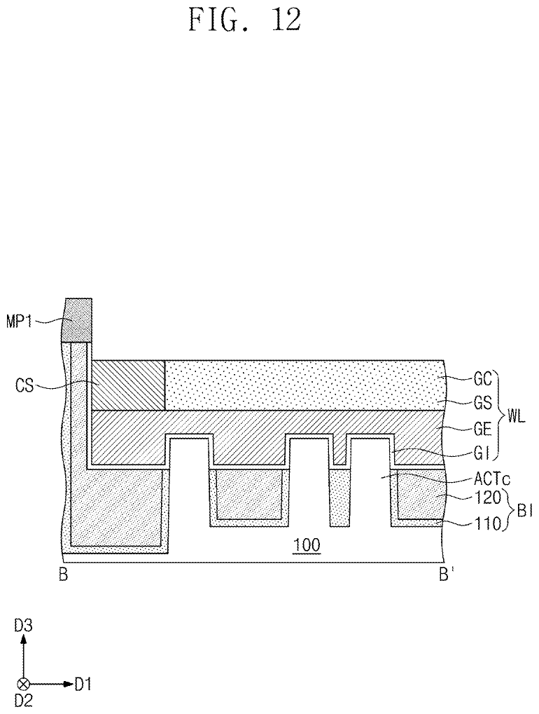

Referring to FIG. 12, the gate intervening pattern GS may be formed. The gate intervening pattern GS may be formed by performing a deposition process after removing the second mask pattern MP2a. The gate capping pattern GC may be formed on the gate intervening pattern GS. The gate capping pattern GC may be formed to have a top surface that is coplanar with a top surface of the connection structure CSa.

After the formation of the gate capping pattern GC, the first mask pattern MP1 may be removed, and then, the interlayer insulating layer IL may be deposited on the boundary device isolation pattern BI and the gate capping pattern GC. After the deposition of the interlayer insulating layer IL, the word line contact plug CT may be formed. The formation of the word line contact plug CT may include forming a trench to penetrate the interlayer insulating layer IL and expose the connection structure CS and filling the trench with a conductive material. As a result of the formation of the word line contact plug CT, the semiconductor device may have the same structure as the semiconductor device 2 of FIG. 4.

In an embodiment, the gate capping pattern GC may be deposited to cover the top surface of the connection structure CSa. The gate capping pattern GC may be formed to have a top surface that is coplanar with a top surface of the boundary device isolation pattern BI, and then, the word line contact plug CT may be formed. The conductive structure 191, which is electrically connected to the word line contact plug CT, may be formed. As a result of the afore-described process, the semiconductor device 3 of FIG. 5 may be formed.

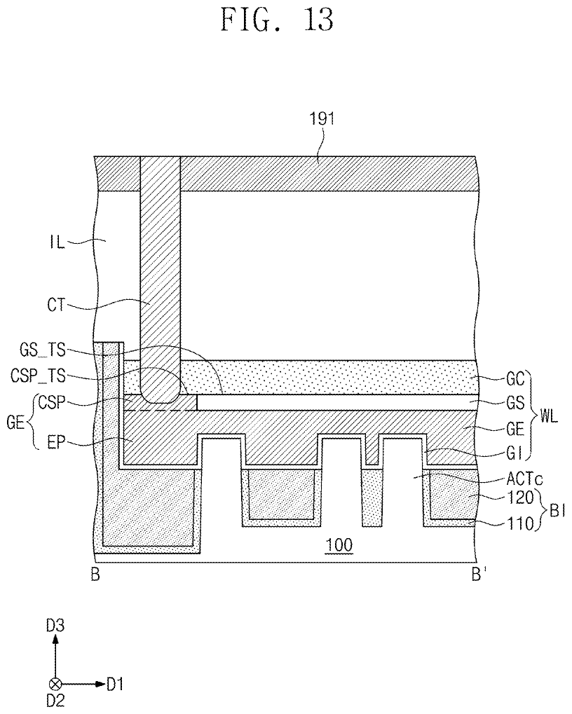

FIG. 13 is a sectional view illustrating a semiconductor device according to an embodiment. In the following description, a previously-described element may be identified by the same reference number without repeating an overlapping description thereof, for concise description.

Referring to FIG. 13, a semiconductor device 5 may include the substrate 100, the cell active pattern ACTc on the substrate 100, the boundary device isolation pattern BI defining the cell active pattern ACTc, the word line WL on the cell active pattern ACTc, the interlayer insulating layer IL on the word line WL, and the word line contact plug CT on the word line WL, in the boundary region BR.

The word line WL may include the gate dielectric pattern GI, the gate electrode GE on the gate dielectric pattern GI, the gate intervening pattern GS on the gate electrode GE, and the gate capping pattern GC on the gate intervening pattern GS.

The gate electrode GE may include an electrode portion EP and a word line connecting portion CSP thereon. The electrode portion EP and the word line connecting portion CSP may form a single object without any interface therebetween. The word line connecting portion CSP and the electrode portion EP may be formed of or include the same material. A top surface CSP_TS of the word line connecting portion CSP may be coplanar with the top surface GS_TS of the gate intervening pattern GS.

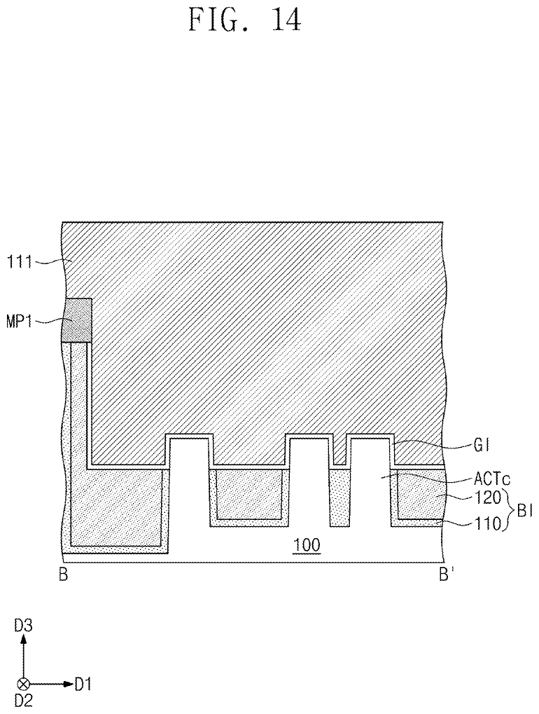

FIGS. 14 to 17 are sectional views illustrating stages in a method of fabricating a semiconductor device according to an embodiment. In the following description, a previously-described element may be identified by the same reference number without repeating an overlapping description thereof, for concise description.

Hereinafter, a method of fabricating the semiconductor device 5 will be described. As shown in FIG. 14, the cell active pattern ACTc may be formed on the substrate 100, the boundary device isolation pattern BI may be formed to define the cell active pattern ACTc, the first mask pattern MP1 and the preliminary gate electrode 111 may be formed on the boundary device isolation pattern BI, and the gate dielectric pattern GI may be formed between the preliminary gate electrode 111 and the boundary device isolation pattern BI, and between the preliminary gate electrode 111 and the cell active pattern ACTc.

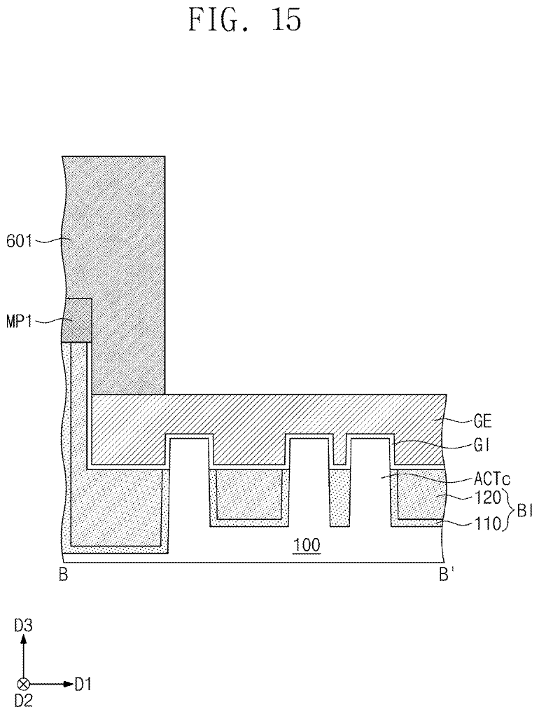

Referring to FIG. 15, the gate electrode GE may be formed by removing a portion of the preliminary gate electrode 111.

After the formation of the gate electrode GE, a connection mask pattern 601 may be formed on the gate electrode GE to cover a region where the word line connecting portion CSP will be formed. The connection mask pattern 601 may be formed to cover the first mask pattern MP1.

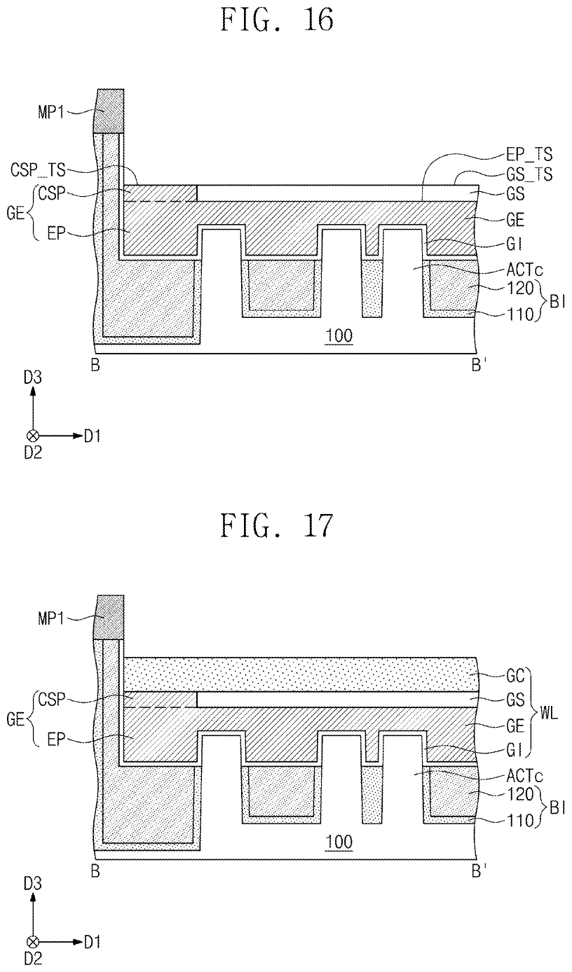

Referring to FIG. 16, the word line connecting portion CSP and the electrode portion EP may be formed by removing a portion of the gate electrode GE exposed by the connection mask pattern 601. That is, the portion of the gate electrode GE exposed by the connection mask pattern 601 may be removed, while a portion of the gate electrode GE veiled by the connection mask pattern 601 may be left under the connection mask pattern 601. Thus, a level of the top surface CSP_TS of the word line connecting portion CSP may be higher than a level of a top surface EP_TS of the electrode portion EP.

Thereafter, the gate intervening pattern GS may be formed. In an embodiment, the gate intervening pattern GS may be formed by a deposition process, which is performed after removing the connection mask pattern 601. The gate intervening pattern GS may be formed to have a top surface located at the same level as the top surface CSP_TS of the word line connecting portion CSP.

Referring to FIG. 17, the gate capping pattern GC may be formed on the gate intervening pattern GS and the word line connecting portion CSP. Since the gate capping pattern GC is formed in the presence of the first mask pattern MP1, the gate capping pattern GC may not be formed on the boundary device isolation pattern BI. The gate capping pattern GC may be used as a part of the word line WL.

After the formation of the gate capping pattern GC, the first mask pattern MP1 may be removed. Thereafter, the interlayer insulating layer IL may be deposited on the boundary device isolation pattern BI and the gate capping pattern GC. After the deposition of the interlayer insulating layer TL, the word line contact plug CT may be formed. The formation of the word line contact plug CT may include forming a trench to penetrate the interlayer insulating layer TL and the gate capping pattern GC and expose the word line connecting portion CSP and filling the trench with a conductive material. The conductive structure 191, which is electrically connected to the word line contact plug CT, may be formed. As a result of the afore-described process, the semiconductor device 5 of FIG. 13 may be formed.

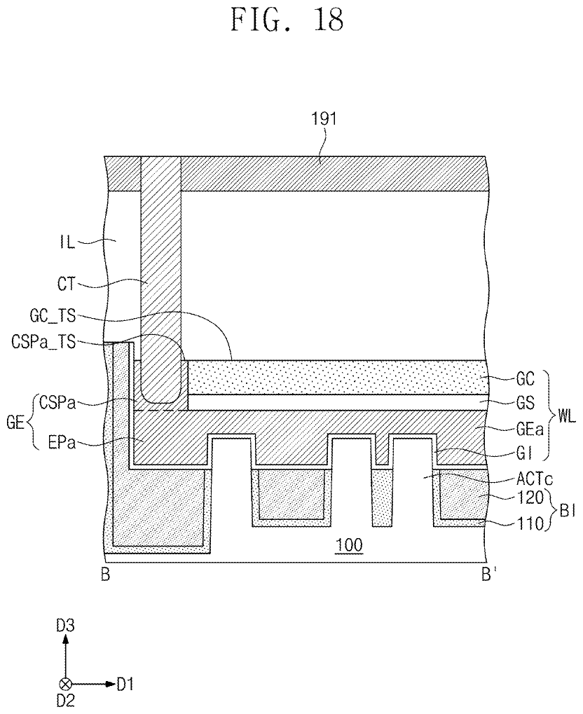

FIG. 18 is a sectional view illustrating a semiconductor device according to an embodiment. In the following description, a previously-described element may be identified by the same reference number without repeating an overlapping description thereof, for concise description.

Referring to FIG. 18, a semiconductor device 6 may include the substrate 100, the cell active pattern ACTc on the substrate 100, the boundary device isolation pattern BI defining the cell active pattern ACTc, the word line WL on the cell active pattern ACTc, the interlayer insulating layer IL on the word line WL, and the word line contact plug CT on the word line WL, in the boundary region BR.

The word line WL may include the gate dielectric pattern GI, a gate electrode GEa on the gate dielectric pattern GI, the gate intervening pattern GS on the gate electrode GEa, and the gate capping pattern GC on the gate intervening pattern GS.

The gate electrode GEa may include an electrode portion EPa and a word line connecting portion CSPa on the electrode portion EPa. The electrode portion EPa and the word line connecting portion CSPa may form a single object without any interface therebetween. The word line connecting portion CSPa and the electrode portion EPa may be formed of or include the same material. A top surface CSPa_TS of the word line connecting portion CSPa may be coplanar with the top surface GC_TS of the gate capping pattern GC. A side surface of the word line connecting portion CSPa may be in contact with the gate intervening pattern GS and the gate capping pattern GC.

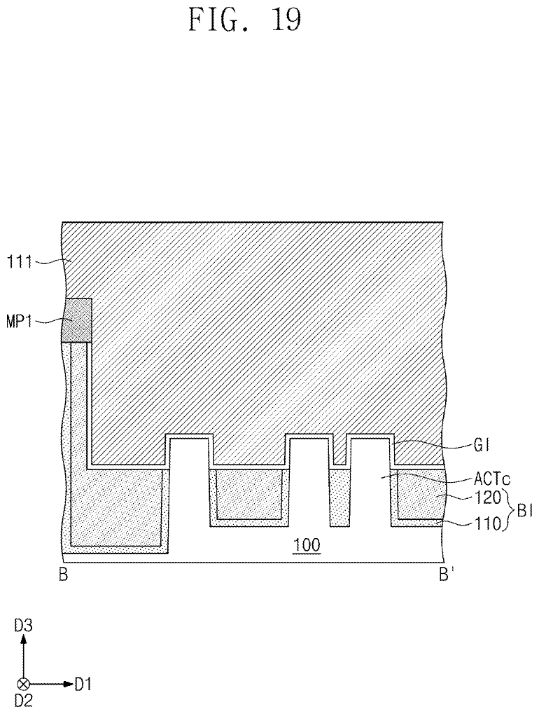

FIGS. 19 to 22 are sectional views illustrating stages in a method of fabricating a semiconductor device according to an embodiment. In the following description, a previously-described element may be identified by the same reference number without repeating an overlapping description thereof, for concise description.

Hereinafter, a method of fabricating the semiconductor device 6 of FIG. 18 will be described. As shown in FIG. 19, the cell active pattern ACTc may be formed on the substrate 100, the boundary device isolation pattern BI may be formed to define the cell active pattern ACTc, the first mask pattern MP1 and the preliminary gate electrode 111 may be formed on the boundary device isolation pattern BI, and the gate dielectric pattern GI may be formed between the preliminary gate electrode 111 and the boundary device isolation pattern BI and between the preliminary gate electrode 111 and the cell active pattern ACTc.

The preliminary gate electrode 111 may be deposited to cover the first mask pattern MP1 and the gate dielectric pattern GI and then may be etched until a top surface thereof is located at the same level as the top surface of the first mask pattern MP1.

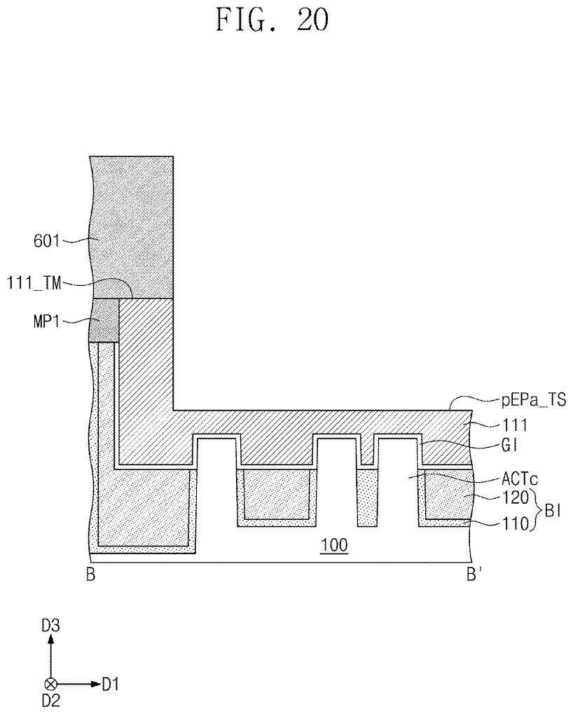

Referring to FIG. 20, the connection mask pattern 601 may be formed on the first mask pattern MP1 and the preliminary gate electrode 111 to cover a region, on which the word line connecting portion CSPa will be formed. A patterning process may be performed to remove a portion of the preliminary gate electrode 111 exposed by the connection mask pattern 601. Accordingly, the preliminary gate electrode 111 may have a top surface pEPa_TS, which is formed in the region exposed by the connection mask pattern 601 and at a level lower than the topmost surface 111_TM of the preliminary gate electrode 111 and is a part of the top surface of the electrode portion EPa.

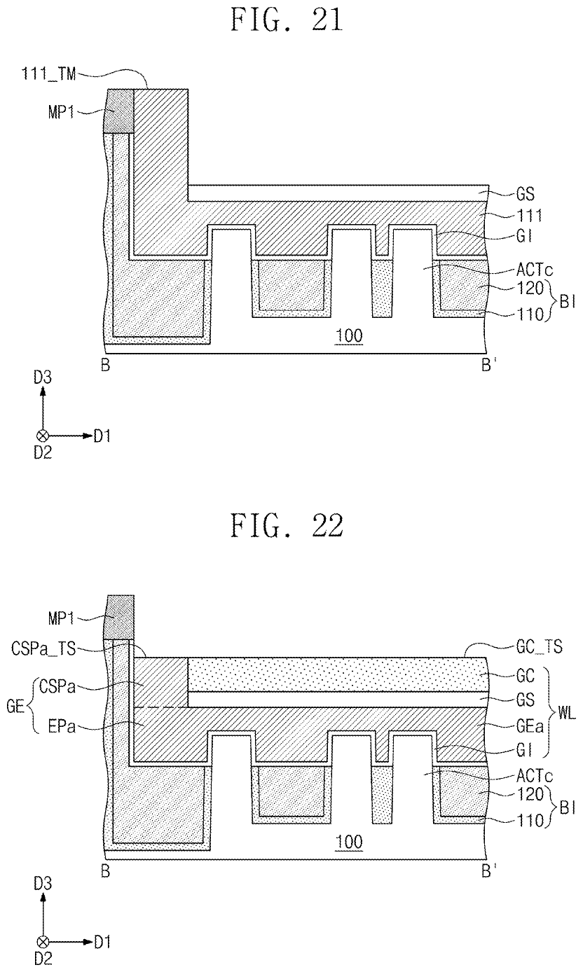

Referring to FIG. 21, the gate intervening pattern GS may be formed. In an embodiment, the gate intervening pattern GS may be formed by a deposition process, which is performed after removing the connection mask pattern 601. The level of the top surface GS_TS of the gate intervening pattern GS may be lower than a level of the topmost surface 111_TS of the preliminary gate electrode 111.

Referring to FIG. 22, an upper portion of the preliminary gate electrode 111 may be removed to form the gate electrode GEa including the word line connecting portion CSPa and the electrode portion EPa. Thereafter, the gate capping pattern GC may be formed on the gate intervening pattern GS. The gate capping pattern GC may be used as a part of the word line WL. The gate capping pattern GC may be formed such that the top surface GC_TS of the gate capping pattern GC is located at the same level as the top surface CSPa_TS of the word line connecting portion CSPa. A side surface of the word line connecting portion CSPa may be in contact with the gate capping pattern GC and the gate intervening pattern GS.

After the formation of the gate capping pattern GC, the first mask pattern MP1 may be removed. Thereafter, the interlayer insulating layer IL may be deposited on the boundary device isolation pattern BI, the gate capping pattern GC, and the word line connecting portion CSPa. After the deposition of the interlayer insulating layer IL, the word line contact plug CT may be formed. The formation of the word line contact plug CT may include forming a trench to penetrate the interlayer insulating layer IL and expose the word line connecting portion CSPa and filling the trench with a conductive material. The conductive structure 191, which is electrically connected to the word line contact plug CT, may be formed. As a result of the afore-described process, the semiconductor device 6 of FIG. 18 may be formed.

By way of summation and review, an embodiment provides a highly-reliable semiconductor device. That is, according to an embodiment, a connection structure may be disposed on a gate electrode in a boundary region and may be electrically connected to a word line contact plug. In other words, a connection structure may be disposed on a gate electrode in a staircase structure (e.g., a stepwise structure) to define a connection region at a different height relative to the top surface of the gate electrode (i.e., the word line), thereby more clearly defining the electrical connection region and reducing contact failure.

Accordingly, it may be possible to reduce a failure which may occur in an electric connection between the word line contact plug and a word line. As a result, a semiconductor device may be fabricated with a decreased likelihood of process failure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate including a cell active region;
a word line on the cell active region, the word line including a gate electrode;
a bit line electrically connected to the cell active region;
a connection structure in the word line and on the gate electrode, the connection structure and the gate electrode including different materials from each other; and
a word line contact plug in contact with the connection structure.

2. The semiconductor device as claimed in claim 1, wherein a level of a top surface of the connection structure is higher than a level of a top surface of the gate electrode.

3. The semiconductor device as claimed in claim 1, further comprising a boundary device isolation pattern on the substrate,
wherein the word line further includes a gate intervening pattern on the gate electrode and a gate capping pattern on the gate intervening pattern, and
wherein a level of a top surface of the gate capping pattern is lower than a level of a topmost surface of the boundary device isolation pattern.

4. The semiconductor device as claimed in claim 3, wherein a level of a bottom surface of the word line contact plug is lower than a level of a top surface of the gate intervening pattern and is higher than a level of a top surface of the gate electrode.

5. The semiconductor device as claimed in claim 3, wherein:
the connection structure penetrates the gate intervening pattern, and
the word line contact plug penetrates the gate capping pattern.

6. The semiconductor device as claimed in claim 3, wherein:
a side surface of the connection structure is in contact with the gate intervening pattern, and
a top surface of the connection structure is in contact with the gate capping pattern.

7. The semiconductor device as claimed in claim 1, wherein a lattice constant of the connection structure is different from a lattice constant of the gate electrode.

8. The semiconductor device as claimed in claim 1, wherein:
the word line further includes a gate dielectric pattern between the gate electrode and the cell active region, and
a side surface of the connection structure is in contact with the gate dielectric pattern.

9. The semiconductor device as claimed in claim 1, wherein the gate electrode and the connection structure are provided to have an interface defined therebetween.

10. The semiconductor device as claimed in claim 1, further comprising a cell active pattern on the substrate and a boundary device isolation pattern defining the cell active pattern, the connection structure not overlapping the cell active pattern.

11. A semiconductor device, comprising:
a substrate including a cell active region;
a word line on the cell active region, the word line including a gate electrode, a gate intervening pattern on the gate electrode, and a gate capping pattern on the gate intervening pattern;
a bit line electrically connected to the cell active region;
a connection structure in the word line, a level of a top surface of the connection structure being higher than a level of a top surface of the gate intervening pattern of the word line; and
a word line contact plug in contact with the connection structure.

12. The semiconductor device as claimed in claim 11, wherein a level of a bottom surface of the word line contact plug is lower than a level of a top surface of the gate capping pattern and is higher than the level of the top surface of the gate intervening pattern.

13. The semiconductor device as claimed in claim 11, wherein the top surface of the connection structure is coplanar with a top surface of the gate capping pattern.

14. The semiconductor device as claimed in claim 11, wherein the level of the top surface of the connection structure is lower than a level of a top surface of the gate capping pattern.

15. The semiconductor device as claimed in claim 14, further comprising a boundary device isolation pattern defining a cell active pattern, the level of the top surface of the gate capping pattern being equal to a level of a topmost surface of the boundary device isolation pattern.

16. The semiconductor device as claimed in claim 15, wherein the boundary device isolation pattern includes at least one of silicon nitride and silicon oxide.

17. The semiconductor device as claimed in claim 11, further comprising an interlayer insulating layer on the gate capping pattern.

18. The semiconductor device as claimed in claim 11, wherein the gate intervening pattern includes polysilicon.

19. A semiconductor device, comprising:
a substrate including a cell region, a peripheral region, and a boundary region between the cell region and the peripheral region;
a cell active pattern on the boundary region;
a boundary device isolation pattern defining the cell active pattern;
a word line on the cell active pattern;
a connection structure;
a word line contact plug connected to the connection structure; and
an interlayer insulating layer enclosing the word line contact plug,
wherein the word line includes:
a gate dielectric pattern on the cell active pattern,
a gate electrode on the gate dielectric pattern,
a gate intervening pattern on the gate electrode, and
a gate capping pattern on the gate intervening pattern,
wherein the connection structure electrically connects the gate electrode to the word line contact plug, the connection structure and the gate electrode including different materials from each other, and the connection structure and the gate electrode having an interface defined therebetween, and
wherein a side surface of the connection structure is in contact with the gate dielectric pattern.

20. The semiconductor device as claimed in claim 19, wherein the connection structure has an electric conductivity higher than an electric conductivity of the gate electrode.
